(19) United States
(12) Patent Application Publication
(10) Pub. No.: US 2011/0199749 A1
(43) Pub. Date: Aug. 18, 2011

(54) Led lead frame structure

(75) Inventors: Pei-Hsuan Lan, Banciao City (TW); Yin-Cheng Chao, Yonghe City (TW); Yu-Bing Lan, Banciao City (TW); Jen-Hua Yang, Luojhuang Village (TW)

(73) Assignee: Forward Electronics Co., Ltd., Taipei City (TW)

(21) Appl. No.: 12/662,818

(22) Filed: May 5, 2010

(30) Foreign Application Priority Data
Feb. 12, 2010 (TW) 099203272

(51) Int. Cl. H01L 23/495

(52) U.S. Cl. 361/813; 257/E23.031

(57) ABSTRACT

An LED support's lead frame structure includes a side frame, a loading piece connected with the side frame, and at least one electrode pin. The electrode pin is located at one side of the loading piece and is spaced apart therefrom. The loading piece has a thickness same as that of the electrode pin. The electrode pin includes, connected in sequence, a first external leading section, a wire-bonding section, and a second external leading section. Both the first and the second external leading sections are connected with the side frame. The wire-bonding section includes a first protrusion. Therefore, the material required for wire-bonding is decreased, and the steps for machining the lead frame are decreased, so that the manufacturing process can be speeded up. This will help LED products miniaturized and the LED structure superior in thermal conductivity.

### BACKGROUND OF THE INVENTION

1. Field of the Invention

The present invention relates to a lead frame structure, and more particularly, to a lead frame structure adapted for the support of a light emitting diode (LED).

2. Description of Related Art

Conventionally, an LED package structure primarily comprises a loading support, a positive-electrode pin, a negative-electrode pin, and an insulating body having a bowl-like recess. An LED chip is bonded on the loading support and is received in the bowl-like recess. Since the insulating body is formed, by injection molding, on the loading support and the electrode pins, whether the insulating body is securely positioned becomes an important factor in affecting the yield rate of products.

Taiwan Utility Model Patent Publication No. M347687 discloses a surface-mounting LED with metallic supports and lead frames, characterized in that an upward-concave positioning recess is provided at the bottom of each electrode pin, such that the injection molding material in forming an insulating body can be filled therein, and encapsulated therewith, so as to enhance a secure positioning of the overall structure thereof. In such a structure, the metallic lead frame used (originating a loading support and the electrode pins), prior to an injection molding step, needs to have a thick-and-thin configuration, namely, where a chip is positioned needs to be thicker.

There is a shortage for the lead frame as mentioned above. This is because in order to form a thick-and-thin configuration for the lead frame, an additional cutting process is required. Nor is it easy for making a lead frame having a thick-and-thin configuration by a one-piece molding measure due to difficulties in controlling flatness, let alone the cost is high.

Further, the metallic loading support, like the electrode pins made of metal, performs in the role of thermal conduction path. However, as mentioned above, the place for positioning the chip on the lead frame is thicker. And a thicker part indicates that is a longer thermal conduction path, resulting in an adversely effect on cooling of the chip.

### SUMMARY OF THE INVENTION

An object of the present invention is to provide an LED lead frame structure, comprising a side frame, a loading piece and a first electrode pin, wherein the first electrode pin is located at one side of the loading piece and is spaced apart therefrom. The loading piece has a thickness same as that of the first electrode pin. The first electrode pin includes, connected in sequence, a first external leading section, a wire-bonding section, and a second external leading section. Both the first and the second external leading sections are connected with the side frame. The wire-bonding section includes a first protrusion.

Through the above-mentioned structure, the golden wire required for wire-bonding is much less than that for the conventional art. In addition, thinner metallic lead frame can be an option so as to make LED products thin, and also the overall manufacturing process can be speeded up, let alone the LED structure is superior in thermal-conduction.

According to the present invention, the loading piece is formed, at least one side, with a declination so as to enhance the ability of encapsulation with the insulating body. The loading piece is also provided with at least one auxiliary material-catching hole with the same purpose in enhancing the ability of encapsulation with the insulating body. The auxiliary material-catching hole includes a tapered section and a diameter-equal section, where the two sections are connected with each other and are open to the bottom and the top of the loading piece, respectively.

The wire-bonding section further includes a second protrusion which, together with the first protrusion, define a concave for receiving a Zener diode. The side frame is provided with at least one positioning hole for the purpose of positioning when machining thereof.

Further, according to the present invention, the lead frame structure further includes a second electrode pin located at another side of the loading piece remote from the first electrode pin. The second electrode pin is spaced apart from the loading piece. The loading piece has a thickness same as that of the second electrode pin.

Other objects, advantages, and novel features of the present invention will become more apparent from the following detailed description when taken in conjunction with the accompanying drawings.

### BRIEF DESCRIPTION OF THE DRAWINGS

FIG. 1 is a plane view illustrating part of an LED lead frame structure according to the present invention;

FIG. 2 is an exploded view illustrating the original metallic frame 1 of an LED lead frame according to the present invention;

FIG. 3 is a perspective view illustrating an LED package structure according to the present invention;

FIG. 4 is a cross-sectional view illustrating the LED package structure as shown in FIG. 3; and

FIG. 5 is a cross-sectional view illustrating an auxiliary material-catching hole shown in FIG. 1.

### DETAILED DESCRIPTION OF THE PREFERRED EMBODIMENTS

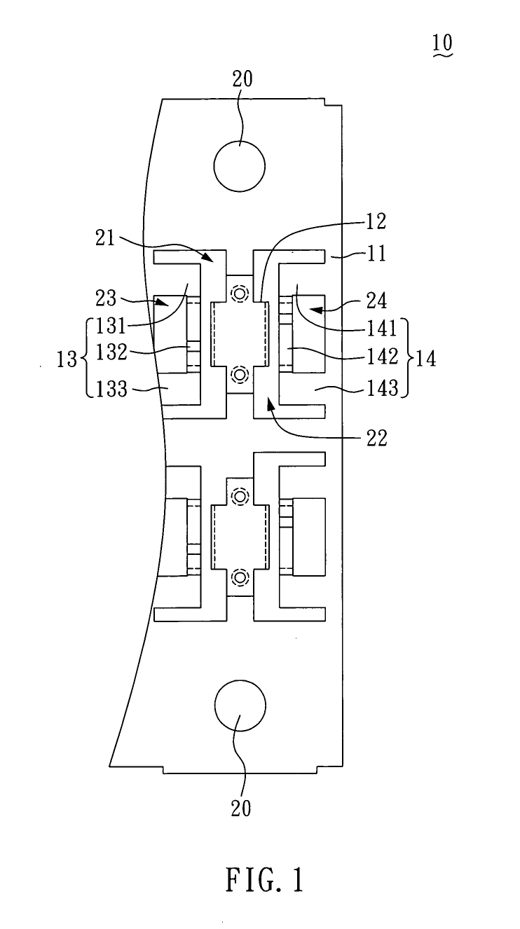

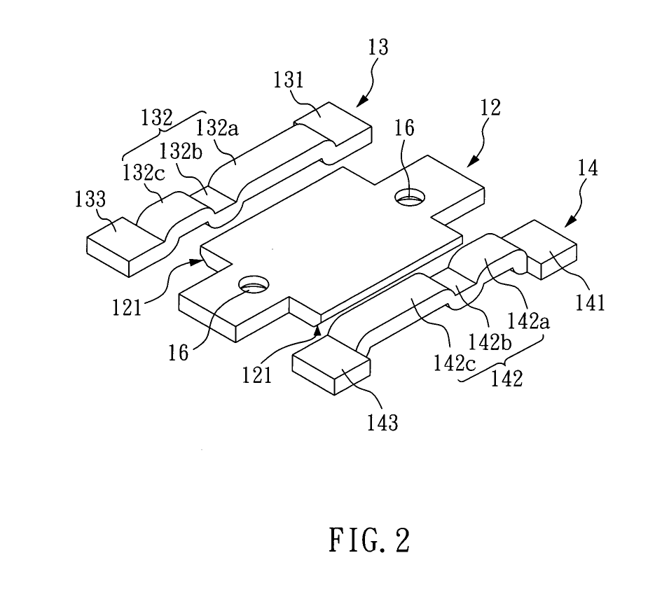

Referring to FIGS. 1 and 2, a metallic thin frame 10 used for LED supports consists of an original material (i.e., an insulating body has not yet been injection-molded) for plural sets of LED supports, where the original material for each set of LED support comprises a side frame 11, a loading piece 12, a positive-electrode pin 13 and a negative-electrode pin 14. The side frame 11 is provided with plural positioning holes 20 for the purpose of positioning when machining thereof.

The loading piece 12, the positive-electrode pin 13 and the negative-electrode pin 14 are all connected with the side frame 11, where the loading piece 12 is, at both sides, spaced apart from the positive-electrode pin 13 and the negative-electrode pin 14, respectively, by gaps 21,22, and where the two electrode pins 13,14 neighbor other gaps 23,24. The gaps 21 to 24 are provided for being filled with molding material when injection molding of the insulating body is undertaken.

The positive-electrode pin 13 includes, in sequence, a first external leading section 131, a wire-bonding section 132, and a second external leading section 133. The positive-electrode pin 13 is connected with the side frame 11 through the first external leading section 131 and the second external leading section 133. The wire-bonding section 132 includes a first protrusion 132a and a second protrusion 132c, where a concave 132b is defined between the two protrusions 132a,132c.

Similarly, the negative-electrode pin 14 includes, in sequence, a first external leading section 141, a wire-bonding section 142, and a second external leading section 143. The negative-electrode pin 14 is connected with the side frame 11 through the first external leading section 141 and the second external leading section 143. The wire-bonding section 142 includes a first protrusion 142a and a second protrusion 142c, where a concave 142b is defined between the two protrusions 142a,142c. In the present invention, the concave 132b of the positive-electrode pin 13 and the concave 142b of the negative-electrode pin 14 are not located correspondingly to each other, but rather contrary to each other. The concaves 132b,142b of the electrode pins 13,14 are provided for receiving Zener diodes (not shown).

In particular, the loading piece 12 and the two electrode pins 13,14 are originated from the same metallic thin frame and have the same thickness. The protrusions 132a, 132c, 142a, 142c can be formed by a press-bending measure, and can be accomplished at the same step together with punching of the gaps 21 to 24 from the metallic thin frame 10. As a result, not only thinner material frame can be adopted in the present invention so as to make products thin, but also the overall manufacturing process can be speeded up.

Further, according to the present invention, the loading piece 12 is provided with two auxiliary material-catching holes 16 for filling with molding material of the insulating body. The auxiliary material-catching holes 16 each includes a tapered section 161 and a diameter-equal section 162, as shown in FIG. 5, where the two sections 161,162 are open to the bottom and the top of the loading piece 12, respectively. With the help of such a structure, the insulating body can be encapsulated and affixed, more securely, on the loading piece 12. The loading piece 12, at sides adjacent to the two electrode pins 13,14, is formed with declinations 121 which will also enhance encapsulation of plastic material.

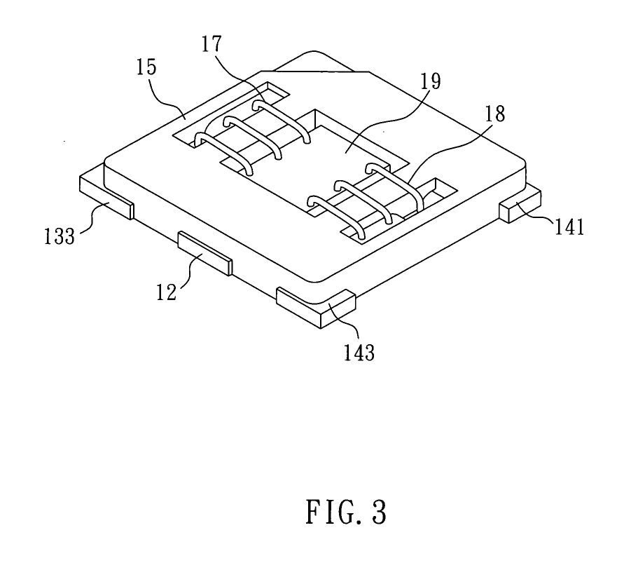

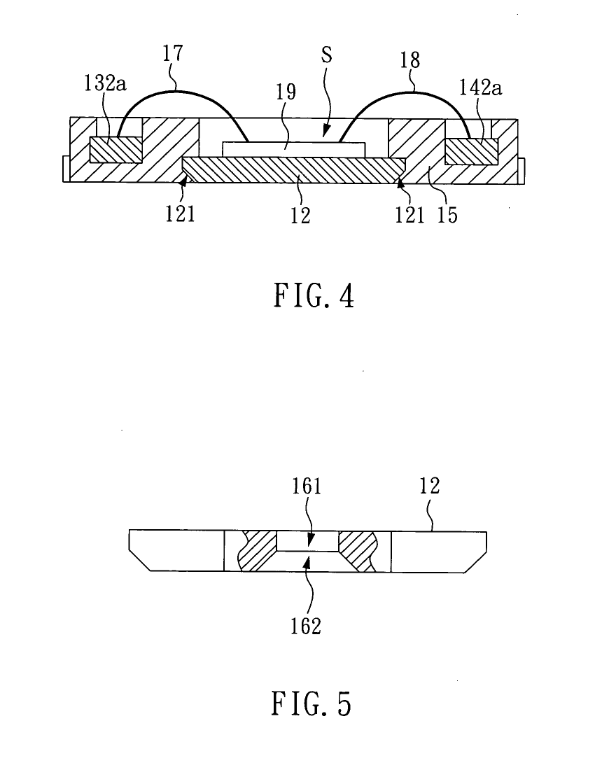

Now referring to FIGS. 3 and 4, an LED package structure, finished with an injection-molding step for the insulating body, a diebonding step, a wire-bonding step, and a step for removal of the side frame 11, comprises the loading piece 12, the positive-electrode pin 13, the negative-electrode pin 14, an insulating body 15, and an LED chip 19. The insulating body 15 encapsulates and affixes, in part, on the loading piece 12 and the two electrode pins 13,14, where the external leading sections 133, 141, 143 of the electrode pins 13,14 extend outward from sides of the insulating body 15.

Further, according to the present invention, the insulating body 15 is provided with a bowl-like recess S, such that the LED chip 19 is bonded on the loading piece 12 and is received in the bowl-like recess S. The LED chip 19 is electrically connected with the protrusions 132a,142a, respectively, via wires 17,18.

It is noted that there is a height difference between the protrusions 132a,142a and the loading piece 12. Therefore, when the LED chip 19 is bonded on the loading piece 12, the height difference between the LED chip 19 and the protrusions 132a,142a becomes less than the above-mentioned height difference, making the material required for the wire-bonding is much less than that for the conventional art. The LED structure, according to the present invention, is superior to the conventional art in terms of thermal-conduction, because the chip-loading portion is not particularly thickened.

Although the present invention has been explained in relation to its preferred embodiments, it is to be understood that many other possible modifications and variations can be made without departing from the scope of the invention as hereinafter claimed.

What is claimed is:

1. An LED lead frame structure, comprising:
a side frame;
a loading piece, being connected with the side frame; and
a first electrode pin;
characterized in that:
the first electrode pin is located at one side of the loading piece and is spaced apart therefrom, and has a thickness same as that of the loading piece; and the first electrode pin includes, connected in sequence, a first external leading section, a wire-bonding section, and a second external leading section; and both the first and the second external leading sections are connected with the side frame; and the wire-bonding section includes a first protrusion.

2. The lead frame structure as claimed in claim 1, wherein the loading piece is formed with at least one declination.

3. The lead frame structure as claimed in claim 1, wherein the wire-bonding section further includes a second protrusion which, together with the first protrusion, define a concave.

4. The lead frame structure as claimed in claim 1, further comprising a second electrode pin located at another side of the loading piece remote from the first electrode pin, and spaced apart from the loading piece, wherein the loading piece has a thickness same as that of the second electrode pin.

5. The lead frame structure as claimed in claim 1, wherein the loading piece is provided with at least one auxiliary material-catching hole.

6. The lead frame structure as claimed in claim 5, wherein the auxiliary material-catching hole includes a tapered section and a diameter-equal section, which are open to the bottom and the top of the loading piece, respectively.

7. The lead frame structure as claimed in claim 1, wherein the side frame is provided with at least one positioning hole.
